(19) United States
(12) Patent Application Publication
(10) Pub. No.: US 2009/0272567 A1
(43) Pub. Date: Nov. 5, 2009

(54) ELECTRONIC DEVICE AND METHOD FOR MAKING THE SAME

(75) Inventors: Chun-Hua HSIA, Taipei County (TW); Ming-Chung Wang, Taipei County (TW); Ching-Shun Wang, Taipei County (TW)

Correspondence Address: LADAS & PARRY, 5670 WILSHIRE BOULEVARD, SUITE 2100, LOS ANGELES, CA, 90036-5679, US

(73) Assignee: ADVANCED CONNECTION TECHNOLOGY INC., Taipei County (TW)

(21) Appl. No.: 12/185,299

(22) Filed: Aug. 4, 2008

(30) Foreign Application Priority Data
May 1, 2008 (TW) 097116071

(51) Int. Cl. H05K 1/16; H05K 3/30

(52) U.S. Cl. 174/260; 29/832

(57) ABSTRACT

An electronic device includes: first and second electronic parts, each of which has a conductive contact; and a plurality of first and second conductive filaments formed on the conductive contacts of the first and second electronic parts, respectively. The first and second electronic parts are connected detachably and coupled electrically to each other through interlocking between the first and second conductive filaments.

### CROSS-REFERENCE TO RELATED APPLICATION

This application claims priority of Taiwanese application no. 097116071, filed on May 1, 2008.

### BACKGROUND OF THE INVENTION

1. Field of the Invention

This invention relates to an electronic device, more particularly to an electronic device including a plurality of first and second conductive filaments formed on first and second conductive contacts of first and second electronic parts, respectively.

2. Description of the Related Art

Recent developments in mounting chips on a substrate, such as a printed circuit board, have focused on surface mounting techniques.

FIGS. 1 and 2 illustrate how a surface mountable device 11 is mounted on a substrate 12 to form a conventional semiconductor device package. The surface mountable device 1 has a plurality of conductive contacts 112 and metal bumps 111 formed on the conductive contacts 112. The substrate 12 has a plurality of conductive contacts 122 and solders 121 formed on the conductive contacts 122 using stencil-printing techniques. During surface mounting, the conductive contacts 112 of the surface mountable device 11 are aligned and brought into contact with the conductive contacts 122 of the substrate 12, and the assembly is subsequently subjected to a reflowing process so that the surface mountable device 11 and the substrate 12 are bonded together and coupled electrically to each other through the reflowed solders 121.

Since a solder paste containing lead is used for the solders 121, which is harmful to the environment, a lead-free solder paste is required. However, the lead-free solder paste has a disadvantage of a high melting point, which results in a high reflowing temperature, which, in turn, results in possible damage to the surface mountable device 11 and the substrate 12.

### SUMMARY OF THE INVENTION

Therefore, an object of the present invention is to provide an electronic device that can overcome the aforesaid drawback associated with the prior art.

Another object of this invention is to provide a method for making the electronic device.

According to one aspect of the present invention, the electronic device comprises: first and second electronic parts, each of which has a conductive contact; and a plurality of first and second conductive filaments formed on the conductive contacts of the first and second electronic parts, respectively. The first and second electronic parts are connected detachably and coupled electrically to each other through interlocking between the first and second conductive filaments.

According to another aspect of this invention, there is provided a method for bonding two electronic parts comprising: (a) forming a plurality of first conductive filaments on one of the electronic parts, and a plurality of second conductive filaments on the other of the electronic parts; and (b) attaching the first conductive filaments to the second conductive filaments so that the electronic parts are connected detachably and coupled electrically to each other through interlocking between the first and second conductive filaments.

### BRIEF DESCRIPTION OF THE DRAWINGS

Other features and advantages of the present invention will become apparent in the following detailed description of the preferred embodiment of this invention, with reference to the accompanying drawings, in which:

FIGS. 1 and 2 are fragmentary schematic views to illustrate how a conventional semiconductor device package is formed;

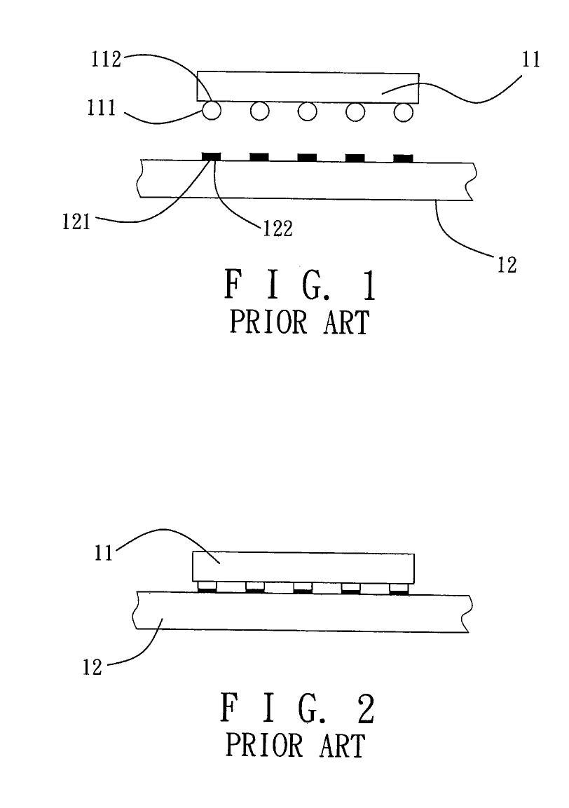

FIG. 3 is a fragmentary schematic exploded view of the preferred embodiment of an electronic device according to this invention; and

FIG. 4 is an assembled schematic view of the preferred embodiment.

### DETAILED DESCRIPTION OF THE PREFERRED EMBODIMENT

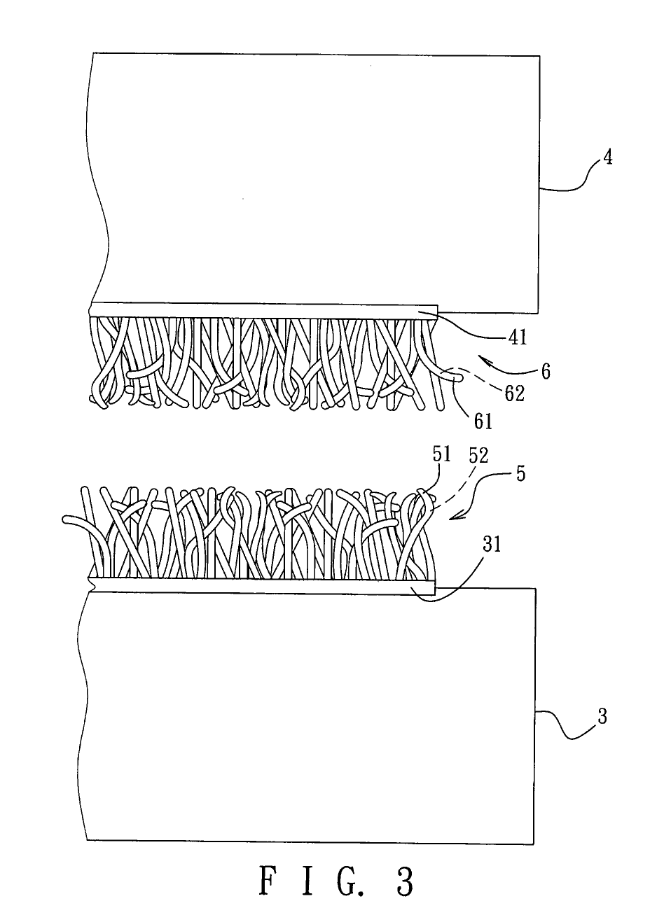

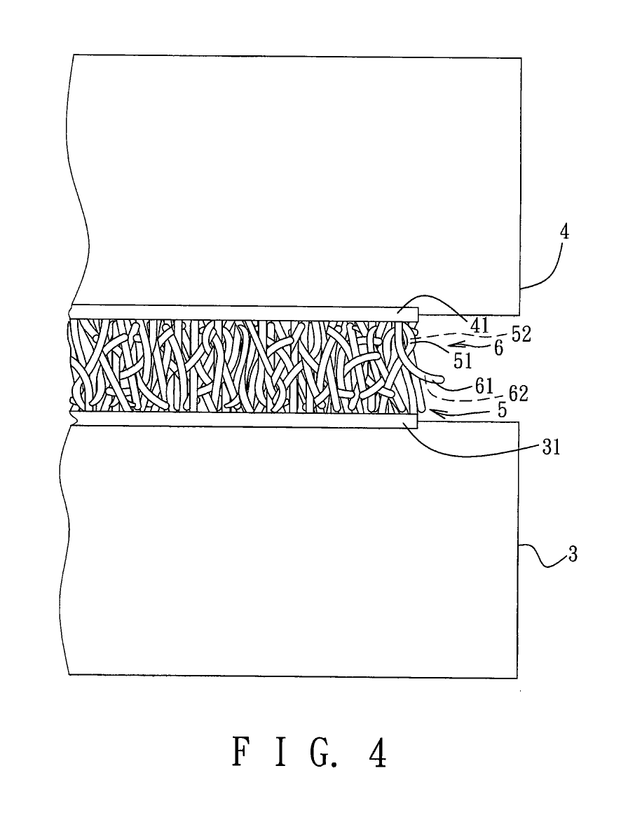

FIGS. 3 and 4 illustrate the preferred embodiment of an electronic device, such as a semiconductor device package, according to this invention.

The electronic device includes: first and second electronic parts 3, 4, each of which has a conductive contact 31, 41; and a plurality of first and second conductive filaments 5, 6 formed on the conductive contacts 31, 41 of the first and second electronic parts 3, 4, respectively. The first and second electronic parts 3, 4 are connected detachably and coupled electrically to each other through interlocking between the first and second conductive filaments 5, 6.

In this embodiment, the first electronic part 3 is a printed circuit board, and the second electronic part 4 is a semiconductor chip.

In this embodiment, each of the first and second conductive filaments 5, 6 has a core 52, 62 and a metal sheath 51, 61 enclosing the core 52, 62.

In this embodiment, the core 52, 62 is made of carbon nanofiber and the metal sheath 51, 61 is made of Ni.

In this embodiment, the first and second conductive filaments 5, 6 interlock with each other in a hook-and-loop engaging manner (see FIG. 4).

In this embodiment, each of the first and second conductive filaments 5, 6 has a nanoscale cross-section so as to provide a sufficient amount of the conductive filaments in a limited area, which increases the connecting force attributed thereto.

This invention also provides a method for bonding two electronic parts 3, 4, including: (a) forming a plurality of the first conductive filaments 5 on the first conductive contact 31 of the first electronic part 3, and a plurality of the second conductive filaments 6 on the second conductive contact 41 of the second electronic part 4; and (b) attaching the first conductive filaments 5 to the second conductive filaments 6 so that the first and second electronic parts 3, 4 are connected detachably and coupled electrically to each other through interlocking between the first and second conductive filaments 5, 6.

In some embodiments, formation of the first and second conductive filaments 5, 6 in step (a) is conducted through semiconductor fabrication techniques, such as chemical vapor deposition (CVD), metal organic chemical vapor deposition (MOCVD), hydride vapor phase epitaxy (HVPE), and vapor-liquid-solid (VLS).

In this embodiment, formation of the core 52, 62 of the first and second conductive filaments 5, 6 is conducted through CVD, and subsequent formation of the metal sheath 51, 61 made of Ni of the first and second conductive filaments 5, 6 is conducted through electroless plating and sputtering.

By forming a plurality of the first and second conductive filaments 5, 6 on the conductive contacts 31, 41 of the first and second electronic parts 3, 4, respectively, the aforesaid drawback associated with the prior art can be eliminated.

With the invention thus explained, it is apparent that various modifications and variations can be made without departing from the spirit of the present invention. It is therefore intended that the invention be limited only as recited in the appended claims.

What is claimed is:

1. An electronic device comprising:
first and second electronic parts, each of which has a conductive contact; and
a plurality of first and second conductive filaments formed on said conductive contacts of said first and second electronic parts, respectively;
wherein said first and second electronic parts are connected detachably and coupled electrically to each other through interlocking between said first and second conductive filaments.

2. The electronic device of claim 1, wherein each of said first and second conductive filaments has a core and a metal sheath enclosing said core.

3. The electronic device of claim 1, wherein said first and second conductive filaments interlock with each other in a hook-and-loop engaging manner.

4. The electronic device of claim 1, wherein each of said first and second conductive filaments has a nanoscale cross-section.

5. The electronic device of claim 1, wherein said first electronic part is a printed circuit board.

6. The electronic device of claim 5, wherein said second electronic part is a semiconductor chip.

7. A method for bonding two electronic parts comprising:
(a) forming a plurality of first conductive filaments on one of the electronic parts, and a plurality of second conductive filaments on the other of the electronic parts; and
(b) attaching the first conductive filaments to the second conductive filaments so that the electronic parts are connected detachably and coupled electrically to each other through interlocking between the first and second conductive filaments.

8. The method of claim 7, wherein formation of the first and second conductive filaments in step (a) is conducted through semiconductor fabrication techniques.
